(19) United States
(12) Patent Application Publication
(10) Pub. No.: US 2025/0324889 A1
(43) Pub. Date: Oct. 16, 2025

(54) DISPLAY DEVICE INCLUDING A DAM STRUCTURE AND ELECTRONIC DEVICE INCLUDING THE SAME

(71) Applicant: SAMSUNG DISPLAY CO., LTD., YONGIN-SI (KR)

(72) Inventors: Donghee Choi, Yongin-si (KR); SUNGKYUN PARK, Yongin-si (KR); YONG-HWAN PARK, Yongin-si (KR)

(21) Appl. No.: 19/009,474

(22) Filed: Jan. 3, 2025

(30) Foreign Application Priority Data
Apr. 15, 2024 (KR) 10-2024-0049796

(51) Int. Cl. H10K 59/80; H10K 59/12; H10K 59/121; H10K 59/40

(52) U.S. Cl. CPC H10K 59/873; H10K 59/1201; H10K 59/40; H10K 59/1213

(57) ABSTRACT

A display device includes an inorganic insulating layer. A touch insulating layer is disposed on the inorganic insulating layer. A touch contact layer is disposed on the touch insulating layer. A touch protection layer is disposed on the touch contact layer. An outer dam is disposed on the inorganic insulating layer, overlapping the peripheral area, including a same material as the touch protection layer, and contacting the inorganic insulating layer. An overcoating layer is disposed on the touch protection layer.

### CROSS-REFERENCE TO RELATED APPLICATION(S)

This application claims priority under 35 U.S.C. § 119 to Korean Patent Application No. 10-2024-0049796, filed on Apr. 15, 2024, the content of which is herein incorporated by reference in its entirety.

### TECHNICAL FIELD

The present disclosure relates to a display device and electronic device including the display device, and, more specifically, to a display device including a dam structure.

### DISCUSSION OF THE RELATED ART

A display device may be divided into a display area and a peripheral area surrounding the display area. An emission layer and an organic layer disposed on the emission layer are formed in the display area, and drivers for driving the emission layer are formed in the peripheral area. A dam may be further formed in the peripheral area, and the dam may prevent organic material of the organic layer from overflowing.

### SUMMARY

A display device includes a substrate including a display area and a peripheral area adjacent to the display area. At least one inorganic insulating layer is disposed on the substrate and overlaps the display area and the peripheral area. An emission layer is disposed on the inorganic insulating layer and overlaps the display area. A touch insulating layer is disposed on the emission layer. A touch contact layer is disposed on the touch insulating layer. A touch protection layer is disposed on the touch contact layer and overlaps the display area. At least one outer dam is disposed on the inorganic insulating layer, overlapping the peripheral area, including a same material as the touch protection layer, and contacting the inorganic insulating layer. An overcoating layer is disposed on the touch protection layer.

The outer dam may directly contact the inorganic insulating layer.

The touch insulating layer and the touch contact layer might not be disposed between the outer dam and the inorganic insulating layer.

The inorganic insulating layer may include an inorganic material, and the touch protection layer and the outer dam may include an organic material.

The touch contact layer may include an organic material.

The display device may further include an active pattern disposed on the substrate, a first gate electrode disposed on the active pattern, and a second gate electrode disposed on the first gate electrode.

The inorganic insulating layer may include a first inorganic insulating layer disposed between the substrate and the active pattern, a second insulating layer disposed between the active pattern and the first gate electrode, and a third insulating layer disposed between the first gate electrode and the second gate electrode.

The display device may further include an encapsulation layer disposed between the inorganic insulating layer and the touch insulating layer. The encapsulation layer may include a first inorganic encapsulation layer disposed on the inorganic insulating layer, an organic encapsulation layer disposed on the first inorganic encapsulation layer, and a second inorganic encapsulation layer disposed on the organic encapsulation layer.

The display device may further include a via insulating layer disposed between the inorganic insulating layer and the emission layer, and overlapping the display area, and at least one inner dam disposed on the inorganic insulating layer, overlapping the peripheral area, including a same material as the via insulating layer, and contacting the inorganic insulating layer.

The display device may further include a first touch electrode disposed on the touch insulating layer, and a second touch electrode disposed on the touch contact layer.

A display device includes a substrate having a display area and a peripheral area adjacent to the display area. An emission layer is disposed on a substrate and overlaps the display area. A touch insulating layer is disposed on the emission layer. A first touch electrode is disposed on the touch insulating layer and overlaps the display area. A touch contact layer is disposed on the touch insulating layer, covering a first touch electrode, and overlapping the display area and the peripheral area. A second touch electrode is disposed on the touch contact layer and overlaps the display area. A touch protection layer is disposed on the touch contact layer, covering the second touch electrode, and overlapping the display area. At least one metal pattern is disposed on the touch contact layer, overlapping the peripheral area, and including a same material as the second touch electrode. At least one outer dam is disposed on the touch contact layer, overlapping the peripheral area, including a same material as the touch protection layer, and covering the metal pattern. An overcoating layer is disposed on the touch protection layer.

The outer dam may directly contact the metal pattern.

The metal pattern may include a metal material, and the touch protection layer and the outer dam may include an organic material.

The touch contact layer may include an organic material.

The metal pattern may contact the touch contact layer in the peripheral area.

The touch contact layer contacting the metal pattern may have an undercut shape.

The display device may further include an active pattern disposed on the substrate, a first gate electrode disposed on the active pattern, a second gate electrode disposed on the first gate electrode, a connection electrode disposed on the second electrode, a pixel electrode disposed between the connection electrode and the emission layer, and a common electrode disposed on the emission layer.

The display device may further include a first inorganic encapsulation layer disposed on the common layer, an organic encapsulation layer disposed on the first inorganic encapsulation layer, and a second inorganic encapsulation layer disposed on the organic encapsulation layer.

The display device may further include at least one via insulating layer disposed under the emission layer and overlapping the display area, and at least one inner dam disposed on the substrate, overlapping the peripheral area, and including a same material as the via insulating layer.

An electronic device includes a display device and a power supply configured to provide power to the display device. The display device includes a substrate including a display area and a peripheral area adjacent to the display area. At least one inorganic insulating layer is disposed on the substrate and overlaps the display area and the peripheral area. An emission layer is disposed on the inorganic insulating layer and overlaps the display area. A touch insulating layer is disposed on the emission layer. A touch contact layer is disposed on the touch insulating layer. A touch protection layer is disposed on the touch contact layer and overlaps the display area. At least one outer dam is disposed on the inorganic insulating layer, overlapping the peripheral area, including a same material as the touch protection layer, and contacting the inorganic insulating layer. An overcoating layer is disposed on the touch protection layer.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a plan view illustrating a display device according to an embodiment of the present invention.

FIG. 2 is a circuit diagram illustrating a pixel included in the display device of FIG. 1.

FIG. 3 is a cross-sectional view illustrating area A of FIG. 1.

FIG. 4 is a cross-sectional view illustrating area B of FIG. 1.

FIGS. 5 to 12 are cross-sectional views illustrating a method of manufacturing the display device of FIG. 4.

FIG. 13 is a plan view illustrating a display device according to an embodiment of the present invention.

FIG. 14 is a cross-sectional view illustrating area C of FIG. 13.

FIGS. 15 to 24 are cross-sectional views illustrating a method of manufacturing the display device of FIG. 14.

FIG. 25 is a block diagram illustrating an electronic device according to an embodiment of the present invention.

### DETAILED DESCRIPTION

In describing embodiments of the present disclosure illustrated in the drawings, specific terminology is employed for sake of clarity. However, the present disclosure is not necessarily intended to be limited to the specific terminology so selected, and it is to be understood that each specific element includes all technical equivalents which operate in a similar manner.

A display device according to embodiments of the present invention may include an outer dam. The outer dam may be formed together with the touch protection layer and may include the same material as the touch protection layer. For example, the outer dam may include organic material. The outer dam may directly contact the inorganic insulating layer. For example, the touch insulating layer and the touch contact layer might not be disposed between the outer dam and the inorganic insulating layer. For example, the touch insulating layer and the touch contact layer may be removed from the area adjacent to the outer dam.

As the outer dam directly contact the inorganic insulating layer, the reliability of the outer dam can be increased. For example, as adhesive force between the outer dam formed of an organic material and the inorganic insulating layer formed of an inorganic material is secured, the outer dam can be firmly attached without being torn. In addition, the outer dam can prevent the planarization layer from overflowing past the outer dam.

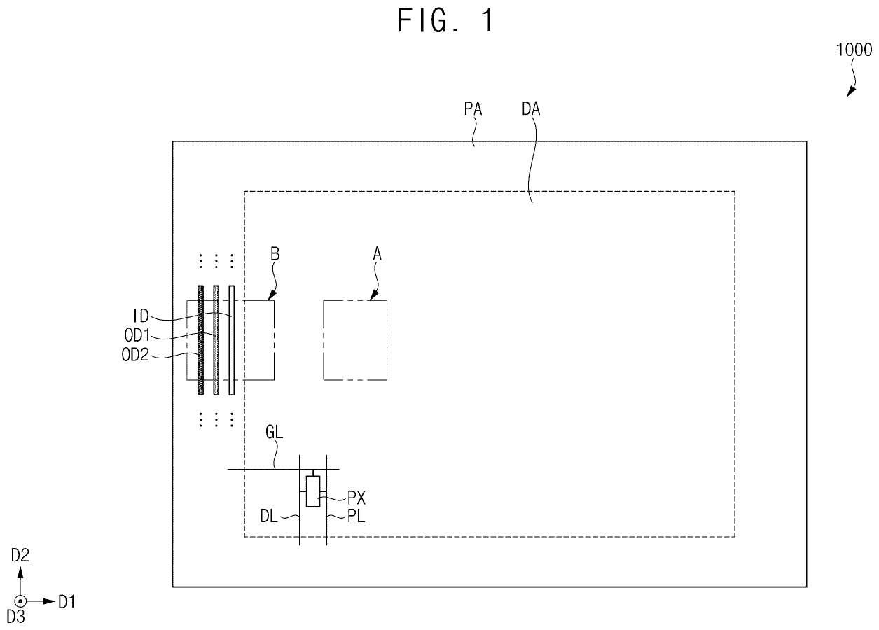

FIG. 1 is a plan view illustrating a display device according to an embodiment of the present invention.

Referring to FIG. 1, a display device 1000, according to an embodiment of the present invention, may be divided into a display area DA and a peripheral area PA.

The display area DA may be defined on a plane consisting of a first direction D1 and a second direction D2 intersecting the first direction D1. At least one pixel PX may be disposed in the display area DA, and the display area DA may display an image.

The peripheral area PA may be adjacent to the display area DA. For example, the peripheral area PA may surround the display area DA. At least one driver may be disposed in the peripheral area PA, and the driver may transmit a signal and/or voltage to the pixel PX. The driver may be instantiated as one or more circuits.

In an embodiment, the driver may include a gate driver, a data driver, and a power supply. The gate driver may transmit a gate signal to the pixel PX through a gate line GL. The data driver may transmit a data voltage to the pixel PX through a data line DL. The power supply may transmit a power voltage to the pixel PX through a power line PL.

In an embodiment, at least one dam may be formed in the peripheral area PA. For example, the dam may surround the display area DA. The dam may accommodate organic material printed on the display area DA. Accordingly, the dam can prevent the organic material from overflowing past the dam.

As shown in FIG. 1, the dam may include an inner dam ID, a first outer dam OD1, and a second outer dam OD2. Each of the inner dam ID, the first outer dam OD1, and the second outer dam OD2 may be arranged side-by-side along the first direction D1 and may extend in the second direction D2. For example, the inner dam ID may be disposed between the display area DA and the first outer dam OD1, and the first outer dam OD1 may be disposed between the inner dam ID and the second outer dam OD2.

However, the present invention is not necessarily limited to this. For example, an additional dam may be formed in the display device 1000 on the upper, lower, and/or right side of the display area DA.

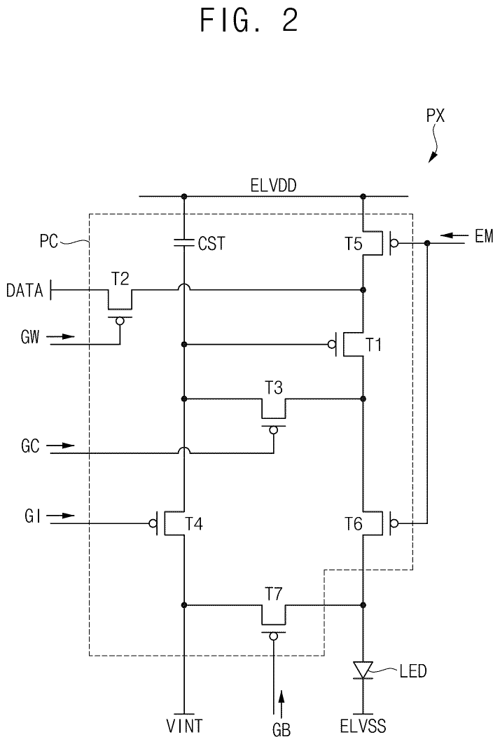

FIG. 2 is a circuit diagram illustrating a pixel included in the display device of FIG. 1.

Referring to FIG. 2, the pixel PX may include a pixel circuit PC and a light emitting diode LED. The pixel circuit PC may provide the driving current to the light emitting diode LED, and the light emitting diode LED may generate light based on the driving current. For example, the light emitting diode LED may include an organic light emitting diode, an inorganic light emitting diode, a nano light emitting diode, etc.

The pixel circuit PC may include a first transistor T1, a second transistor T2, a third transistor T3, a fourth transistor T4, a fifth transistor T5, a sixth transistor T6, a seventh transistor T7, and a storage capacitor CST.

The light emitting diode LED may include a first terminal (e.g., anode terminal) and a second terminal (e.g., cathode terminal). The first terminal of the light emitting diode LED may be connected to the sixth transistor T6 and the seventh transistor T7, and the second terminal may be provided with a second power voltage ELVSS. The light emitting diode LED can generate light with a brightness corresponding to the driving current.

The storage capacitor CST may include a first terminal and a second terminal. The first terminal of the storage capacitor CST may be connected to the first transistor T1, and the second terminal of the storage capacitor CST may receive a first power voltage ELVDD. The storage capacitor CST may maintain the voltage level of the gate terminal of the first transistor T1 during the deactivation period of a first gate signal GW.

The first transistor T1 may include a gate terminal, a first terminal, and a second terminal. The gate terminal of the first transistor T1 may be connected to the first terminal of the storage capacitor CST. The first terminal of the first transistor T1 may be connected to the second transistor T2 and may receive the data voltage DATA. The second terminal of the first transistor T1 may be connected to the sixth transistor T6. The first transistor T1 may generate the driving current based on the voltage difference between the gate terminal and the first terminal. For example, the first transistor T1 may be referred to as a driving transistor.

The second transistor T2 may include a gate terminal, a first terminal, and a second terminal. The gate terminal of the second transistor T2 may receive the first gate signal GW through the gate line GL.

The second transistor T2 may be turned on or off in response to the first gate signal GW. For example, when the second transistor T2 is a PMOS transistor, the second transistor T2 may be turned off when the first gate signal GW has a positive voltage level, and may be turned on when the first gate signal GW has a negative voltage level. The first terminal of the second transistor T2 may receive the data voltage DATA through the data line DL. The second terminal of the second transistor T2 may provide the data voltage DATA to the first terminal of the first transistor T1 during the period in which the second transistor T2 is turned on. For example, the second transistor T2 may be referred to as a switching transistor.

The third transistor T3 may include a gate terminal, a first terminal, and a second terminal. The gate terminal of the third transistor T3 may receive a second gate signal GC. The first terminal of the third transistor T3 may be connected to the second terminal of the first transistor T1. The second terminal of the third transistor T3 may be connected to the gate terminal of the first transistor T1.

The third transistor T3 may be turned on or off in response to the second gate signal GC. For example, when the third transistor T3 is a PMOS transistor, the third transistor T3 may be turned off when the second gate signal GC has a positive voltage level, and may be turned on when the second gate signal GC has a negative voltage level.

During a period in which the third transistor T3 is turned on in response to the second gate signal GC, the third transistor T3 may diode-connect the first transistor T1. As used herein, the phrase “diode-connect” may mean that a drain of a transistor (e.g., a MOSFET) is directly connected a gate of a transistor. This configuration causes the transistor to behave like a diode. Accordingly, the third transistor T3 can compensate for the threshold voltage of the first transistor T1. For example, the third transistor T3 may be referred to as a compensation transistor.

The fourth transistor T4 may include a gate terminal, a first terminal, and a second terminal. The gate terminal of the fourth transistor T4 may receive a third gate signal GI. The first terminal of the fourth transistor T4 may be connected to the gate terminal of the first transistor T1. The second terminal of the fourth transistor T4 may receive the initialization voltage VINT.

The fourth transistor T4 may be turned on or off in response to the third gate signal GI. For example, when the fourth transistor T4 is a PMOS transistor, the fourth transistor T4 maybe turned off when the third gate signal GI has a positive voltage level, and may be turned on when the third gate signal GI has a negative voltage level.

During a period in which the fourth transistor T4 is turned on by the third gate signal GI, the initialization voltage VINT may be provided to the gate terminal of the first transistor T1. Accordingly, the fourth transistor T4 can initialize the gate terminal of the first transistor T1 to the initialization voltage VINT. For example, the fourth transistor T4 may be referred to as a gate initialization transistor.

The fifth transistor T5 may include a gate terminal, a first terminal, and a second terminal. The gate terminal of the fifth transistor T5 may receive the emission control signal EM. The first terminal of the fifth transistor T5 may receive the first power voltage ELVDD. The second terminal of the fifth transistor T5 may be connected to the first transistor T1. When the fifth transistor T5 is turned on in response to the emission control signal EM, the fifth transistor T5 may provide the first power voltage ELVDD to the first transistor T1.

The sixth transistor T6 may include a gate terminal, a first terminal, and a second terminal. The gate terminal of the sixth transistor T6 may receive the emission control signal EM. The first terminal of the sixth transistor T6 may be connected to the first transistor T1. The second terminal of the sixth transistor T6 may be connected to the light emitting diode LED. When the sixth transistor T6 is turned on in response to the emission control signal EM, the sixth transistor T6 may provide the driving current to the light emitting diode LED.

The seventh transistor T7 may include a gate terminal, a first terminal, and a second terminal. The gate terminal of the seventh transistor T7 may receive the fourth gate signal GB. The first terminal of the seventh transistor T7 may be connected to the light emitting diode LED. The second terminal of the seventh transistor T7 may receive the initialization voltage VINT.

When the seventh transistor T7 is turned on in response to the fourth gate signal GB, the seventh transistor T7 may provide the initialization voltage VINT to the light emitting diode LED. Accordingly, the seventh transistor T7 can initialize the first terminal of the light emitting diode LED to the initialization voltage VINT. For example, the seventh transistor T7 may be referred to as an anode initialization transistor.

However, the structure of the pixel circuit PC is not necessarily limited to the above-described structure. For example, the number of transistors, number of capacitors, and types of transistors (PMOS, NMOS, etc.) included in the pixel circuit PC can be appropriately set as needed.

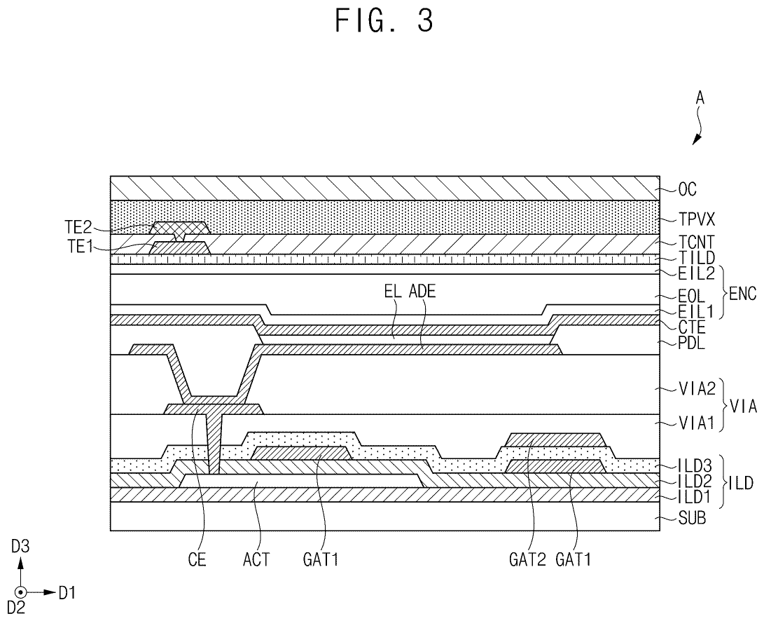

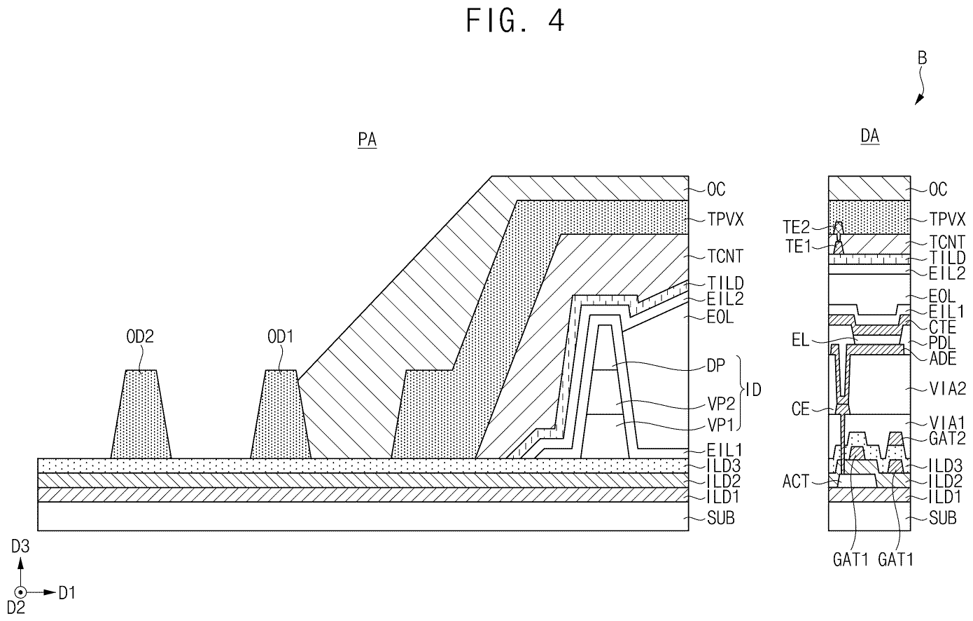

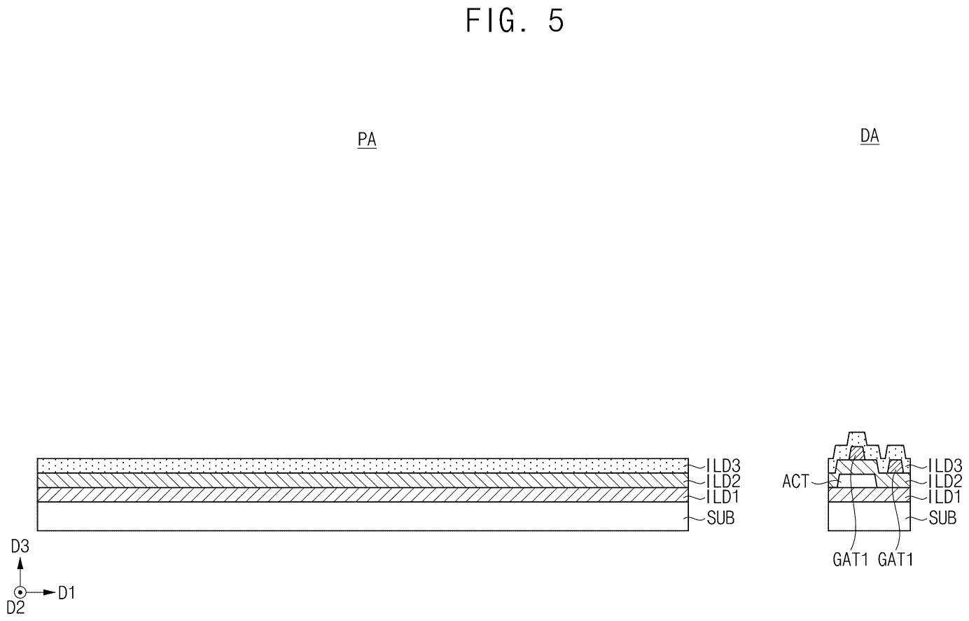

FIG. 3 is a cross-sectional view illustrating area A of FIG. 1. FIG. 4 is a cross-sectional view illustrating area B of FIG. 1. FIGS. 5 to 12 are cross-sectional views illustrating a method of manufacturing the display device of FIG. 4.

Referring to FIG. 3, in the display area DA, the display device 1000 may include a substrate SUB, an inorganic insulating layer ILD, an active pattern ACT, a first gate electrode GAT1, a second gate electrode GAT2, a connection electrode CE, a via insulating layer VIA, a pixel electrode ADE, a pixel defining layer PDL, an emission layer EL, a common electrode CTE, an encapsulation layer ENC, a touch insulating layer TILD, a first touch electrode TE1, a touch contact layer TCNT, a second touch electrode TE2, a touch protection layer TPVX, and a overcoating layer OC.

In an embodiment, the inorganic insulating layer ILD may include a first inorganic insulating layer ILD1, a second inorganic insulating layer ILD2, and a third inorganic insulating layer ILD3. The via insulating layer VIA may include a first via insulating layer VIA1 and a second via insulating layer VIA2. The encapsulation layer ENC may include a first inorganic encapsulation layer EIL1, an organic encapsulation layer EOL, and a second inorganic encapsulation layer EIL2.

The substrate SUB may include a transparent or opaque material. In an embodiment, examples of materials that can be used as the substrate SUB may include glass, quartz, and plastic. These can be used alone or in combination with each other. In addition, the substrate SUB may be composed of a single layer or multiple layers by combining a plurality of single layers.

The first inorganic insulating layer ILD1 may be disposed on the substrate SUB and may overlap the display area DA and the peripheral area PA (see FIG. 4). In an embodiment, the first inorganic insulating layer ILD1 may include an inorganic material. Examples of materials that can be used as the inorganic material may include silicon oxide, silicon nitride, and silicon oxynitride. These can be used alone or in combination with each other. In addition, the first inorganic insulating layer ILD1 may be composed of a single layer or multiple layers in combination with each other.

The first inorganic insulating layer ILD1 may prevent metal atoms or impurities from diffusing from the substrate SUB into the active pattern ACT. In addition, the first inorganic insulating layer ILD1 can control the rate at which heat is provided during the crystallization process to form the active pattern ACT.

The active pattern ACT may be disposed on the first inorganic insulating layer ILD1. In an embodiment, the active pattern ACT may include a silicon semiconductor material or an oxide semiconductor material. Examples of the silicon semiconductor material that can be used as the active pattern ACT may include amorphous silicon and polycrystalline silicon. Examples of the oxide semiconductor material that can be used as the active pattern ACT may be InGaZnO (IGZO), InSnZnO (ITZO), etc. In addition, the oxide semiconductor material may further include indium (In), gallium (Ga), tin (Sn), zirconium (Zr), vanadium (V), hafnium (Hf), cadmium (Cd), germanium (Ge), chromium (Cr), titanium (Ti), zinc (Zn), etc. These can be used alone or in combination with each other. In addition, the active pattern ACT may be composed of a single layer or multiple layers by combining a plurality of single layers.

The second inorganic insulating layer ILD2 may be disposed on the first inorganic insulating layer ILD1 and may cover the active pattern ACT. The second inorganic insulating layer ILD2 may overlap the display area DA and the peripheral area PA (see FIG. 4). In an embodiment, the second inorganic insulating layer ILD2 may include an inorganic material. Examples of inorganic materials that can be used as the second inorganic insulating layer ILD2 may include silicon oxide, silicon nitride, and silicon oxynitride. These can be used alone or in combination with each other. In addition, the second inorganic insulating layer ILD2 may be composed of a single layer or multiple layers in combination with each other.

The first gate electrode GAT1 may be disposed on the second inorganic insulating layer ILD2. In an embodiment, the first gate electrode GAT1 may include metal, alloy, conductive metal oxide, transparent conductive material, etc. Examples of materials that can be used as the first gate electrode GAT1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These can be used alone or in combination with each other. In addition, the first gate electrode GAT1 may be composed of a single layer or multiple layers by combining a plurality of single layers.

The third inorganic insulating layer ILD3 may be disposed on the second inorganic insulating layer ILD2 and may cover the first gate electrode GAT1. The third inorganic insulating layer ILD3 may overlap the display area DA and the peripheral area PA (see FIG. 4). In an embodiment, the third inorganic insulating layer ILD3 may include an inorganic material. Examples of inorganic materials that can be used as the third inorganic insulating layer ILD3 may include silicon oxide, silicon nitride, and silicon oxynitride. These can be used alone or in combination with each other. In addition, the third inorganic insulating layer ILD3 may be composed of a single layer or multiple layers in combination with each other.

The second gate electrode GAT2 may be disposed on the third inorganic insulating layer ILD3. In an embodiment, the second gate electrode GAT2 may include metal, alloy, conductive metal oxide, transparent conductive material, etc.

The first via insulating layer VIA1 may be disposed on the third inorganic insulating layer ILD3 and may cover the second gate electrode GAT2. In an embodiment, the first via insulating layer VIA1 may include an organic material. Examples of organic materials that can be used as the first via insulating layer VIA1 may include photoresist, polyacrylic resin, polyimide resin, and acrylic resin. These can be used alone or in combination with each other. In addition, the first via insulating layer VIA1 may be composed of a single layer or multiple layers in combination with each other.

The connection electrode CE may be disposed on the first via insulating layer VIA1 and may be connected to the active pattern ACT. In an embodiment, the connection electrode CE may include metal, alloy, conductive metal oxide, transparent conductive material, etc.

The second via insulating layer VIA2 may be disposed on the first via insulating layer VIA1 and may cover the connection electrode CE. In an embodiment, the second via insulating layer VIA2 may include an organic material. Examples of organic materials that can be used as the second via insulating layer VIA2 may include photoresist, polyacrylic resin, polyimide resin, and acrylic resin. These can be used alone or in combination with each other. In addition, the second via insulating layer VIA2 may be composed of a single layer or multiple layers in combination with each other.

The pixel electrode ADE may be disposed on the second via insulating layer VIA2 and may be connected to the connection electrode CE. In an embodiment, the pixel electrode ADE may include metal, alloy, conductive metal oxide, transparent conductive material, etc.

The pixel defining layer PDL may be disposed on the second via insulating layer VIA2. An opening may be formed in the pixel defining layer PDL to expose the pixel electrode ADE. In an embodiment, the pixel defining layer PDL may include an organic material.

The emission layer EL may be disposed on the pixel electrode ADE and may overlap the display area DA. The common electrode CTE may be disposed on the emission layer EL. The emission layer EL may emit light based on the voltage difference between the pixel electrode ADE and the common electrode CTE.

The first inorganic encapsulation layer EIL1 may be disposed on the common electrode CTE. In an embodiment, the first inorganic encapsulation layer EIL1 may include an inorganic material.

The organic encapsulation layer EOL may be disposed on the first inorganic encapsulation layer EIL1. In an embodiment, the organic encapsulation layer EOL may include an organic material.

The second inorganic encapsulation layer EIL2 may be disposed on the organic encapsulation layer EOL. In an embodiment, the second inorganic encapsulation layer EIL2 may include an inorganic material.

The touch insulating layer TILD may be disposed on the second inorganic encapsulation layer EIL2. In an embodiment, the touch insulating layer TILD may include an inorganic material.

The first touch electrode TE1 may be disposed on the touch insulating layer TILD. In an embodiment, the first touch electrode TE1 may include metal, alloy, conductive metal oxide, transparent conductive material, etc.

The touch contact layer TCNT may be disposed on the touch insulating layer TILD and may cover the first touch electrode TE1. In an embodiment, the touch contact layer TCNT may include an organic material.

The second touch electrode TE1 may be disposed on the touch contact layer TCNT and may be connected to the first touch electrode TE1. For example, the second touch electrode TE2 may contact the first touch electrode TE1 through a contact hole formed in the touch contact layer TCNT. In an embodiment, the second touch electrode TE2 may include metal, alloy, conductive metal oxide, transparent conductive material, etc.

The touch protection layer TPVX may be disposed on the touch contact layer TCNT and may cover the second touch electrode TE2. In an embodiment, the touch protection layer TPVX may include an organic material.

The overcoating layer OC may be disposed on the touch protection layer TPVX. In an embodiment, the overcoating layer OC may include an organic material.

Referring to FIG. 4, in the peripheral area PA, the display device 1000 may include the substrate SUB, the first inorganic insulating layer ILD1, the second inorganic insulating layer ILD2, the third inorganic insulating layer ILD3, the inner dam ID, the first inorganic encapsulation layer EIL1, the organic encapsulation layer EOL, the second inorganic encapsulation layer EIL2, the touch insulating layer TILD, the touch contact layer TCNT, the touch protection layer TPVX, the first outer dam OD1, the second outer dam OD2, and the overcoating layer OC.

In an embodiment, the inner dam ID may include a first via pattern VP1, a second via pattern VP2, and a pixel defining pattern DP. The first via pattern VP1 may be formed together with the first via insulating layer VIA1 and may include the same material as the first via insulating layer VIA1. The second via pattern VP2 may be formed together with the second via insulating layer VIA2 and may include the same material as the second via insulating layer VIA2. The pixel defining pattern DP may be formed together with the pixel defining layer PDL and may include the same material as the pixel defining layer PDL. As used herein, the phrase, “formed together” may mean that the elements in question are formed as part of a same process step, at the same time or close together in time, and may include one or more of the same materials.

In an embodiment, in the peripheral area PA, the inner dam ID may directly contact the third inorganic insulating layer ILD3.

As the inner dam ID directly contacts the third inorganic insulating layer ILD3, a reliability of the inner dam ID can be increased. For example, as the adhesive force between the inner dam ID formed of an organic material and the third inorganic insulating layer ILD3 formed of an inorganic material is secured, the inner dam ID may be firmly attached without being torn.

However, the present invention is not necessarily limited to this. In an embodiment, the third inorganic insulating layer ILD3 may be removed from the peripheral area PA, and the inner dam ID may directly contact the second inorganic insulating layer ILD2 or the first inorganic insulating layer ILD1. In an embodiment, a separate additional inorganic insulating layer may be further formed in the peripheral area PA, and the inner dam ID may directly contact the additional inorganic insulating layer.

The inner dam ID may overlap the peripheral area PA, may be disposed between the first outer dam OD1 and the display area DA, and may accommodate the organic encapsulation layer EOL. Accordingly, the inner dam ID can prevent the organic encapsulation layer EOL from overflowing past the inner dam ID.

In an embodiment, the first outer dam OD1 may be formed together with the touch protection layer TPVX and may include the same material as the touch protection layer TPVX. For example, the first outer dam OD1 may include an organic material.

In an embodiment, in the peripheral area PA, the first outer dam OD1 may directly contact the third inorganic insulating layer ILD3. For example, the touch insulating layer TILD and the touch contact layer TCNT might not be disposed between the first outer dam OD1 and the third inorganic insulating layer ILD3. For example, the touch insulating layer TILD and the touch contact layer TCNT may be removed from an area adjacent to the first outer dam OD1.

As the first outer dam OD1 directly contacts the third inorganic insulating layer ILD3, a reliability of the first outer dam OD1 can be increased. For example, as the adhesive force between the first outer dam OD1 formed of an organic material and the third inorganic insulating layer ILD3 formed of an inorganic material is secured, the first outer dam OD1 may be firmly attached without being torn.

However, the present invention is not necessarily limited thereto. In an embodiment, the third inorganic insulating layer ILD3 may be removed from the peripheral area PA, and the first outer dam OD1 may directly contact the second inorganic insulating layer ILD2 or the first inorganic insulating layer ILD1. In an embodiment, the first inorganic encapsulation layer EIL1 or the second inorganic encapsulation layer EIL2 may further extend into the peripheral area PA, and the first outer dam OD1 may directly contact the first inorganic encapsulation layer EIL1 or the second inorganic encapsulation layer EIL2. In an embodiment, a separate additional inorganic insulating layer may be further formed in the peripheral area PA, and the first outer dam OD1 may directly contact the additional inorganic insulating layer.

The first outer dam OD1 may overlap the peripheral area PA, may be disposed between the second outer dam OD2 and the inner dam ID, and can accommodate the overcoating layer OC. Accordingly, the first outer dam OD1 can prevent the overcoating layer OC from overflowing past the first outer dam OD1.

In an embodiment, the second outer dam OD2 may be formed together with the touch protection layer TPVX and may include the same material as the touch protection layer TPVX. For example, the second outer dam OD2 may include an organic material.

In an embodiment, in the peripheral area PA, the second outer dam OD2 may directly contact the third inorganic insulating layer ILD3. For example, the touch insulating layer TILD and the touch contact layer TCNT might not be disposed between the second outer dam OD2 and the third inorganic insulating layer ILD3. For example, the touch insulating layer TILD and the touch contact layer TCNT may be removed from the area adjacent to the second outer dam OD2.

As the second outer dam OD2 directly contact with the third inorganic insulating layer ILD3, a reliability of the second outer dam OD2 may be increased. For example, as the adhesive force between the second outer dam OD2 formed of an organic material and the third inorganic insulating layer ILD3 formed of an inorganic material is secured, the second outer dam OD2 may be firmly attached without being torn.

However, the present invention is not necessarily limited to this. In an embodiment, the third inorganic insulating layer ILD3 may be removed from the peripheral area PA, and the second outer dam OD2 may directly contact the second inorganic insulating layer ILD2 or the first inorganic insulating layer ILD1. In an embodiment, the first inorganic encapsulation layer EIL1 or the second inorganic encapsulation layer EIL2 may further extend into the peripheral area PA, and the second outer dam OD2 may directly contact the first inorganic encapsulation layer EIL1 or the second inorganic encapsulation layer EIL2. In an embodiment, a separate additional inorganic insulating layer may be further formed in the peripheral area PA, and the second outer dam OD2 may directly contact the additional inorganic insulating layer.

The second outer dam OD2 may overlap the peripheral area PA, may be adjacent to the first outer dam OD1, and can accommodate the overcoating layer OC. Accordingly, the second outer dam OD2 can prevent the overcoating layer OC from overflowing past the second outer dam OD2.

Referring to FIG. 5, the substrate SUB, the first inorganic insulating layer ILD1, the second inorganic insulating layer ILD2, and the third inorganic insulating layer ILD3 may be sequentially formed in the display area DA and the peripheral area PA. The active pattern ACT and the first gate electrode GAT1 may be formed between the first to third inorganic insulating layers ILD1, ILD2, and ILD3 in the display area DA.

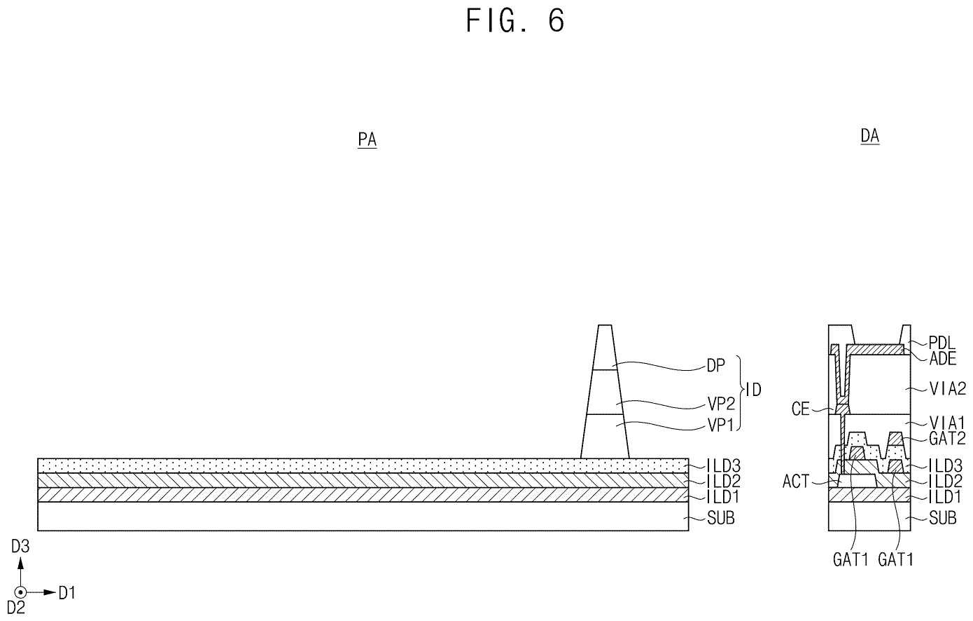

Referring to FIG. 6, in the display area DA, the second gate electrode GAT2, the first via insulating layer VIA1, the connection electrode CE, the second via insulating layer VIA2, the pixel electrode ADE, and the pixel defining layer PDL may be formed sequentially.

In the peripheral area PA, the first via pattern VP1 may be formed together with the first via insulating layer VIA1, the second via pattern VP2 may be formed together with the second via insulating layer VIA2, and the pixel defining pattern DP may be formed together with the pixel defining layer PDL.

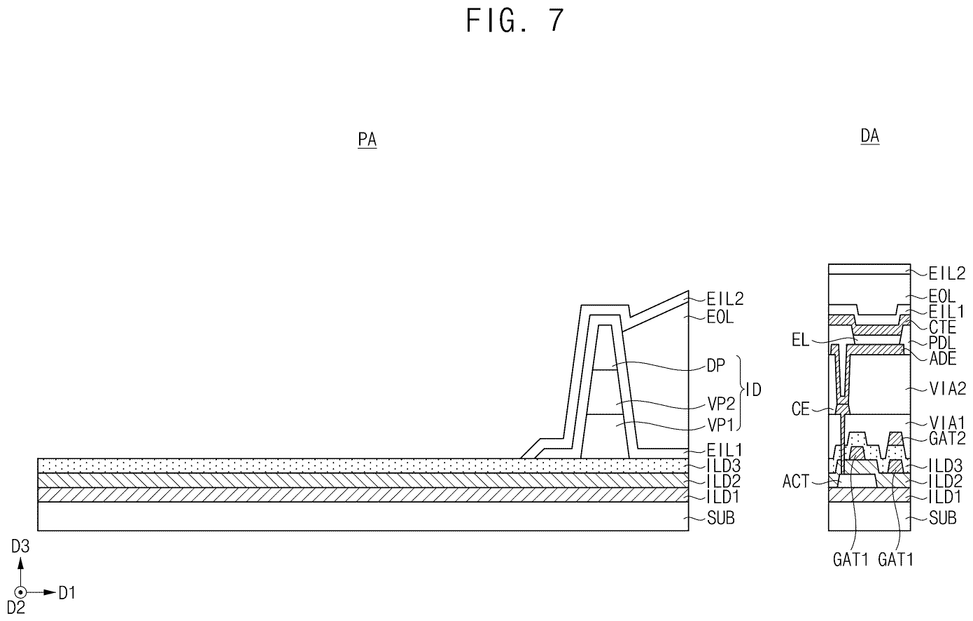

Referring to FIG. 7, in the display area DA, the emission layer EL, the common electrode CTE, the first inorganic encapsulation layer EIL1, the organic encapsulation layer EOL, and the second inorganic encapsulation layer EIL2 may be formed sequentially.

In the peripheral area PA, the first inorganic encapsulation layer EIL1, the organic encapsulation layer EOL, and the second inorganic encapsulation layer EIL2 may be formed sequentially.

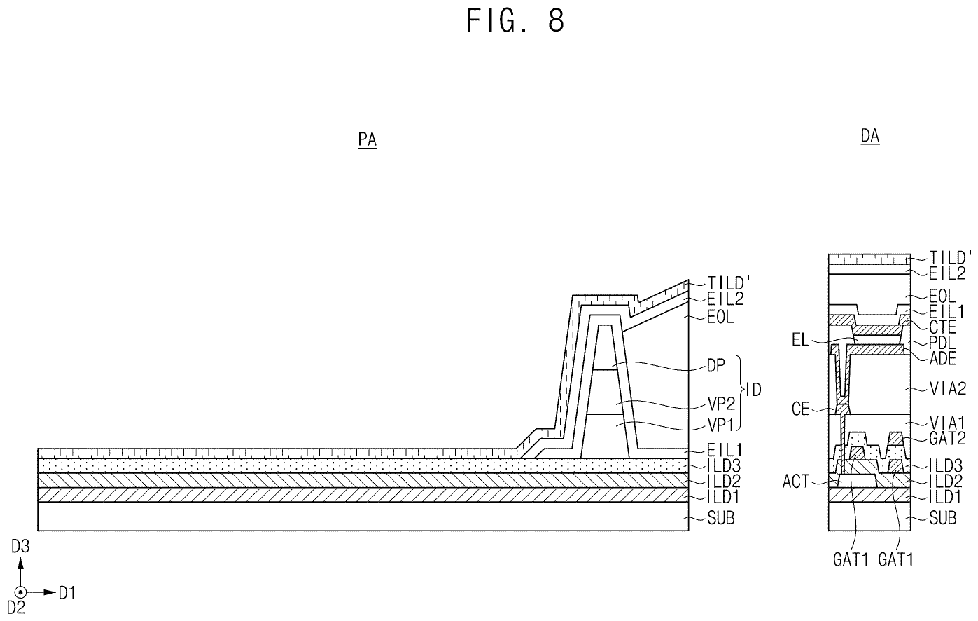

Referring to FIG. 8, a preliminary touch insulating layer TILD′ may be formed in the display area DA and the peripheral area PA.

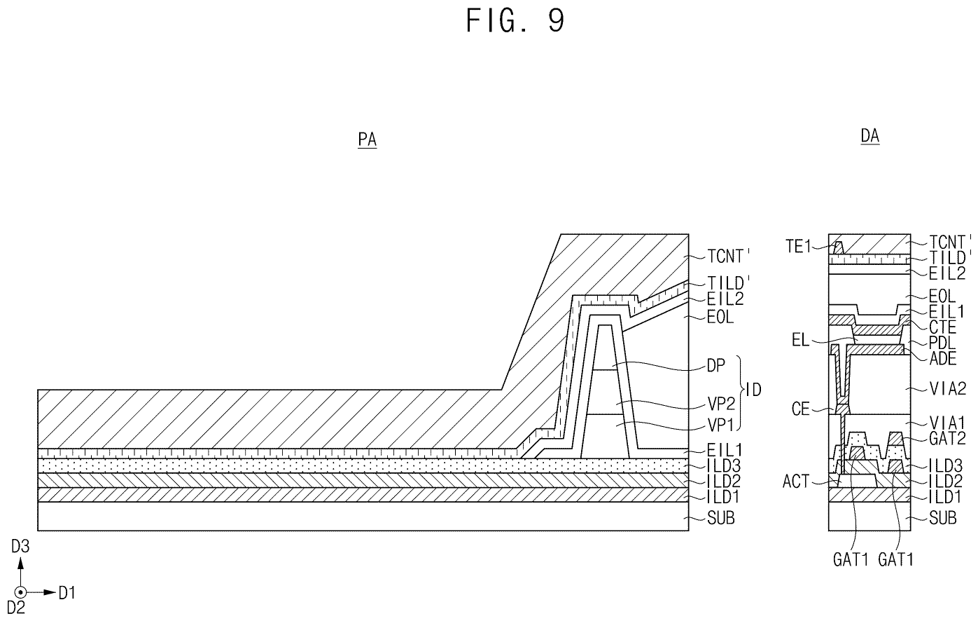

Referring to FIG. 9, in the display area DA, the first touch electrode TE1 may be formed on the preliminary touch insulating layer TILD′, and the preliminary touch contact layer TCNT′ covering the first touch electrode TE1 may be formed in the display area DA and the peripheral area PA.

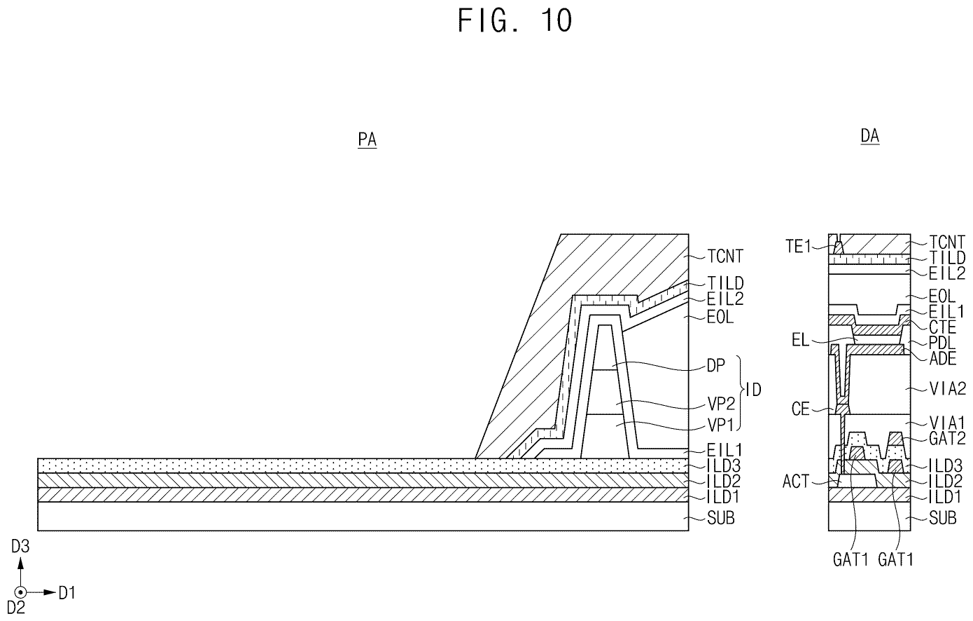

Referring to FIG. 10, a contact hole may be formed in the preliminary touch contact layer TCNT′ in the display area DA.

In the peripheral area PA, the preliminary touch contact layer TCNT′ and the preliminary touch insulating layer TILD′ may be removed. For example, the preliminary touch contact layer TCNT′ and the preliminary touch insulating layer TILD′ may be removed together while the contact hole is formed in the preliminary touch contact layer TCNT′. Accordingly, the touch insulating layer TILD and the touch contact layer TCNT may be formed.

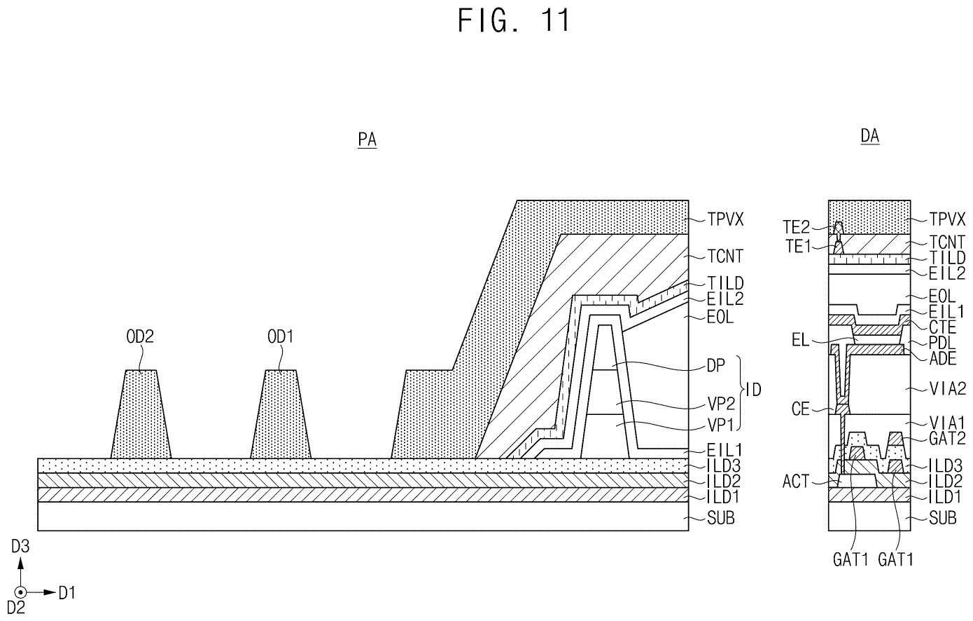

Referring to FIG. 11, the second touch electrode TE2 and the touch protection layer TPVX may be sequentially formed in the display area DA.

In the peripheral area PA, the first outer dam OD1 and the second outer dam OD2 may be formed together with the touch protection layer TPVX.

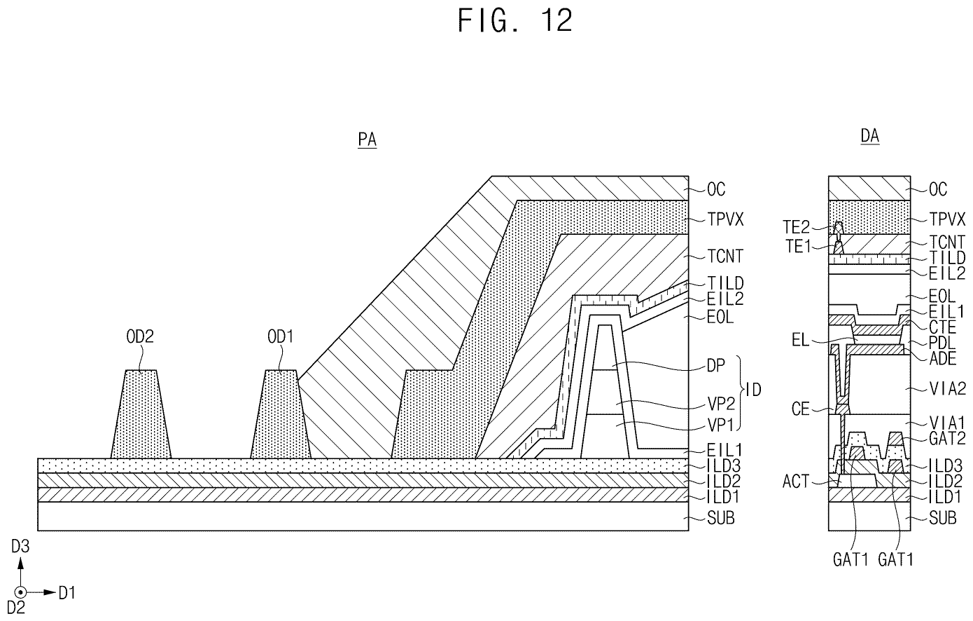

Referring to FIG. 12, the overcoating layer OC may be formed in the display area DA and the peripheral area PA. The overcoating layer OC may extend toward the peripheral area PA bordering the first outer dam OD1.

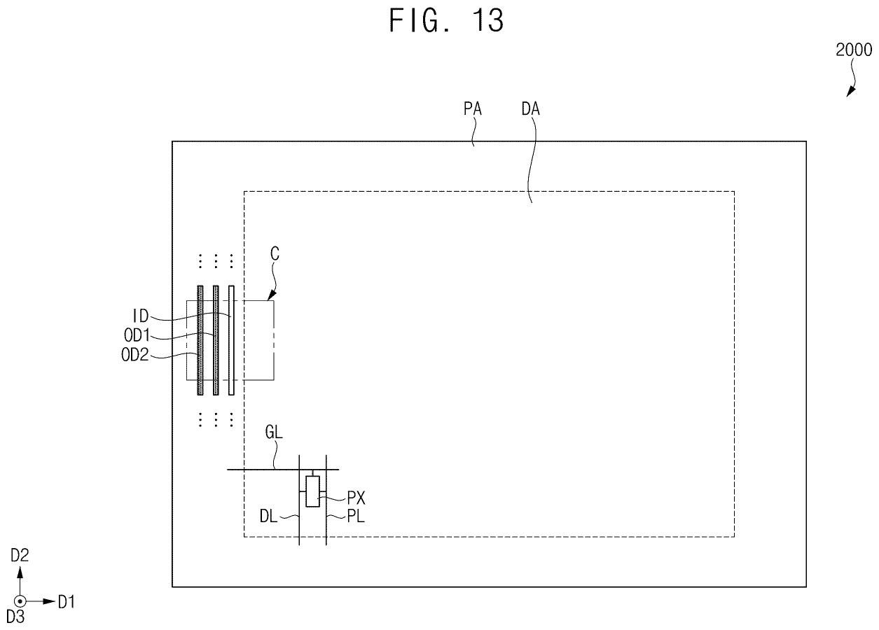

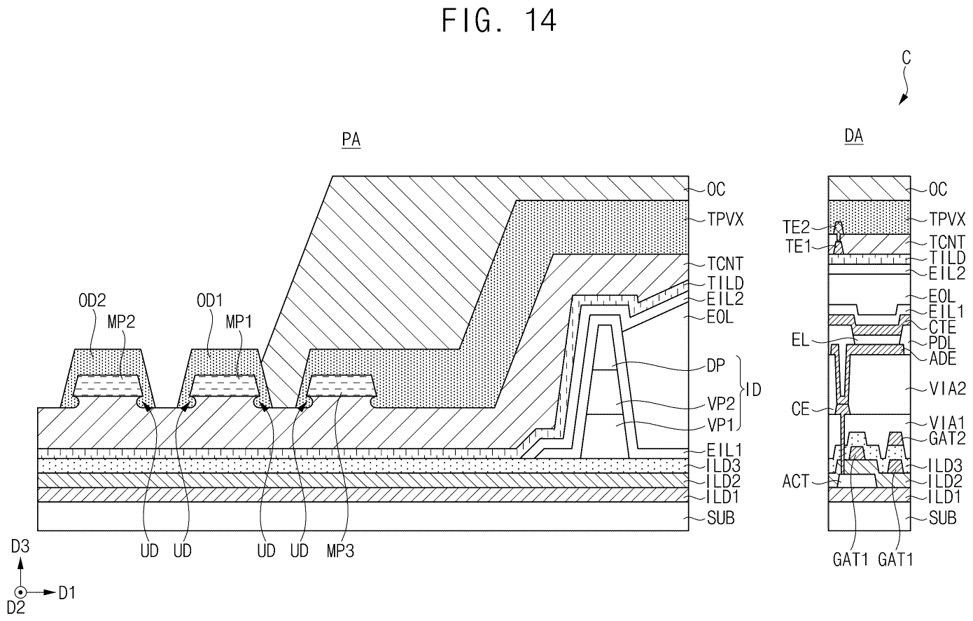

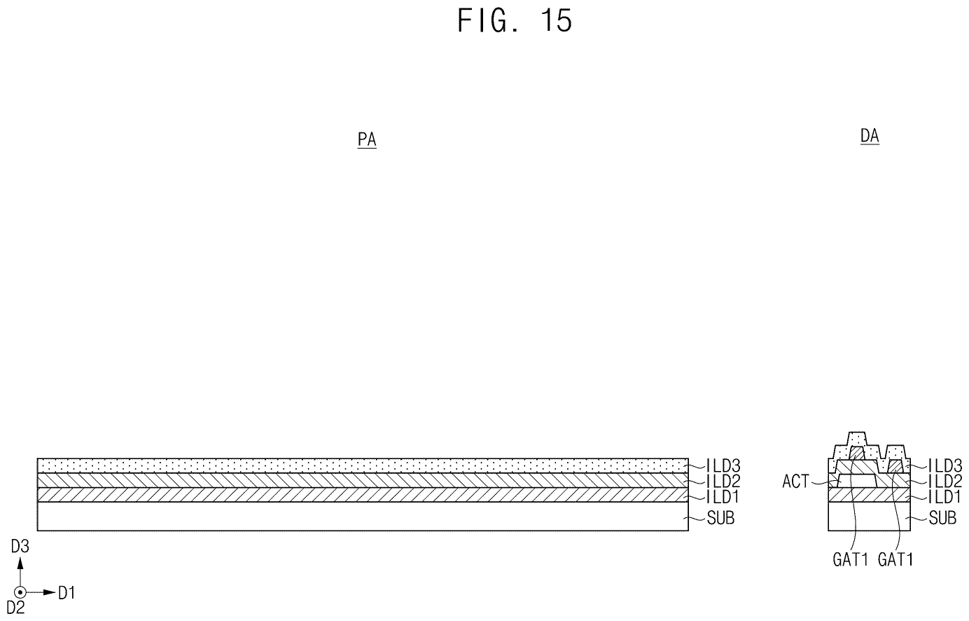

FIG. 13 is a plan view illustrating a display device according to an embodiment of the present invention. FIG. 14 is a cross-sectional view illustrating area C of FIG. 13. FIGS. 15 to 24 are cross-sectional views illustrating a method of manufacturing the display device of FIG. 14.

Referring to FIG. 13, a display device 2000, according to an embodiment of the present invention, may be divided into a display area DA and a peripheral area PA.

In an embodiment, the structure of the display device 2000 in the display area DA may be substantially the same as the structure of the display device 1000 in the display area DA. Hereinafter, the display device 2000 in the peripheral area PA will be mainly described. To the extent that an element is not described in detail with respect to this figure, it may be understood that the element is at least similar to a corresponding element that has been described elsewhere within the present disclosure.

Referring to FIG. 14, in the peripheral area PA, the display device 2000 may include the substrate SUB, the first inorganic insulating layer ILD1, the second inorganic insulating layer ILD2, the third inorganic insulating layer ILD3, the inner dam ID, the first inorganic encapsulation layer EIL1, the organic encapsulation layer EOL, the second inorganic encapsulation layer EIL2, the touch insulating layer TILD, a touch contact layer TCNT, a first metal pattern MP1, a second metal pattern MP2, a third metal pattern MP3, a touch protection layer TPVX, a first outer dam OD1, a second outer dam OD2, and the overcoating layer OC.

However, the substrate SUB, the first inorganic insulating layer ILD1, the second inorganic insulating layer ILD2, the third inorganic insulating layer ILD3, the inner dam ID, the first inorganic encapsulation layer EIL1, the organic encapsulation layer EOL, the second inorganic encapsulation layer EIL2, and the overcoating layer OC may be substantially the same as the substrate SUB, the first inorganic insulating layer ILD1, the second inorganic insulating layer ILD2, the third inorganic insulating layer ILD3, the inner dam ID, the first inorganic encapsulation layer EIL1, the organic encapsulation layer EOL, the second inorganic encapsulation layer EIL2, and the overcoating layer OC described with reference to FIG. 4.

In an embodiment, the touch insulating layer TILD may extend from the display area DA to the peripheral area PA, and may overlap the first outer dam OD1 and the second outer dam OD2.

In an embodiment, the touch contact layer TCNT may be disposed on the touch insulating layer ILD, may extend from the display area DA to the peripheral area PA, and may overlap the first outer dam OD1 and the second outer dam OD2.

In an embodiment, the first metal pattern MP1, the second metal pattern MP2, and the third metal pattern MP3 may be disposed on the touch contact layer TCNT, and may contact the touch contact layer TCNT in the peripheral area PA. In addition, the touch contact layer TCNT contacting the first metal pattern MP1 may have an undercut shape UD, the touch contact layer TCNT contacting the second metal pattern MP2 may have an undercut shape UD, and the touch contact layer TCNT contacting the third metal pattern MP3 may have an undercut shape UD.

In an embodiment, the first metal pattern MP1, the second metal pattern MP2, and the third metal pattern MP3 may overlap the peripheral area PA. For example, the third metal pattern MP3 may be disposed between the first metal pattern MP1 and the display area DA, and the first metal pattern MP1 may be disposed between the second metal pattern MP2 and the third metal patterns MP3.

In an embodiment, the first to third metal patterns MP1, MP2, and MP3 may be floating (e.g., not connected to a defined reference potential, such as ground or a power signal). In an embodiment, a predetermined signal and/or voltage may be applied to the first to third metal patterns MP1, MP2, and MP3.

In an embodiment, the first metal pattern MP1, the second metal pattern MP2, and the third metal pattern MP3 may be formed together with the second touch electrode TE2, and may include a same material as the second touch electrode TE2. For example, the first metal pattern MP1, the second metal pattern MP2, and the third metal pattern MP3 may include a metal material, where a metal material is a metal, a metal alloy, a metal oxide, or any other molecules including metal atoms.

In an embodiment, the first outer dam OD1 may be formed together with the touch protection layer TPVX and may include the same material as the touch protection layer TPVX. For example, the first outer dam OD1 may include an organic material.

In an embodiment, in the peripheral area PA, the first outer dam OD1 may cover the first metal pattern MP1. For example, the first outer dam OD1 may be formed on the first metal pattern MP1 and may directly contact the first metal pattern MP1.

As the first outer dam OD1 directly contact the first metal pattern MP1, a reliability of the first outer dam OD1 may be increased. For example, as the adhesive force between the first outer dam OD1 formed of an organic material and the first metal pattern MP1 formed of a metal material is secured, the first outer dam OD1 may be firmly attached without being torn.

In addition, the undercut shape UD may be formed in the touch contact layer TCNT that contacts the first metal pattern MP1. Due to the structure of the undercut shape UD, the reliability of the first outer dam OD1 can be further increased.

The first outer dam OD1 may overlap the peripheral area PA, may be disposed between the second outer dam OD2 and the inner dam ID, and can accommodate the overcoating layer OC. Accordingly, the first outer dam OD1 can prevent the overcoating layer OC from overflowing past the first outer dam OD1.

In an embodiment, the second outer dam OD2 may be formed together with the touch protection layer TPVX and may include the same material as the touch protection layer TPVX. For example, the second outer dam OD1 may include an organic material.

In an embodiment, in the peripheral area PA, the second outer dam OD2 may cover the second metal pattern MP2. For example, the second outer dam OD2 may be formed on the second metal pattern MP2 and may directly contact the second metal pattern MP2.

As the second outer dam OD2 directly contact the second metal pattern MP2, a reliability of the second outer dam OD2 may be increased. For example, as the adhesive force between the second outer dam OD2 formed of an organic material and the second metal pattern MP2 formed of a metal material is secured, the second outer dam OD2 may be firmly attached without being torn.

In addition, the undercut shape UD may be formed in the touch contact layer TCNT that contacts the second metal pattern MP2. Due to the structure of the undercut shape UD, the reliability of the second outer dam OD2 can be further increased.

The second outer dam OD2 may overlap the peripheral area PA, may be adjacent to the first outer dam OD1, and can accommodate the overcoating layer OC. Accordingly, the second outer dam OD2 can prevent the overcoating layer OC from overflowing past the second outer dam OD2.

The overcoating layer OC may extend to the peripheral area PA bordering the first outer dam OD1 (or the second outer dam OD2). The overcoating layer OC may be flattened upper surfaces of the display area DA and the peripheral area PA, and thus waviness of the display device 1000 can be prevented.

Referring to FIG. 15, the substrate SUB, the first inorganic insulating layer ILD1, the second inorganic insulating layer ILD2, and the third inorganic insulating layer ILD3 may be formed sequentially in the display area DA and the peripheral area PA. The active pattern ACT and the first gate electrode GAT1 may be formed between the first to third inorganic insulating layers ILD1, ILD2, and ILD3 in the display area DA.

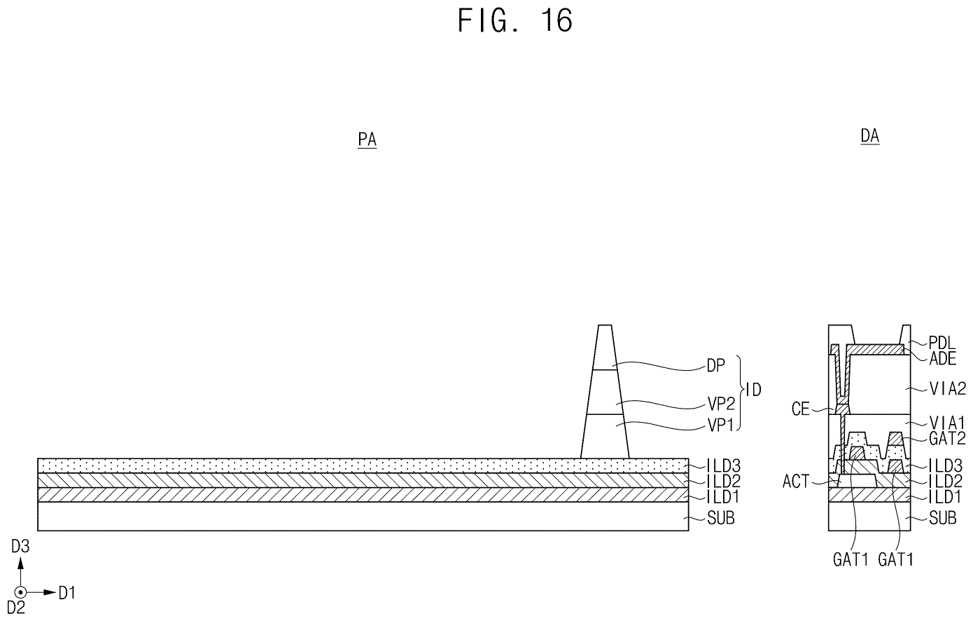

Referring to FIG. 16, in the display area DA, the second gate electrode GAT2, the first via insulating layer VIA1, the connection electrode CE, the second via insulating layer VIA2, the pixel electrode ADE, and the pixel defining layer PDL may be formed sequentially.

In the peripheral area PA, the first via pattern VP1 may be formed together with the first via insulating layer VIA1, the second via pattern VP2 may be formed together with the second via insulating layer VIA2, and the pixel defining pattern DP may be formed together with the pixel defining layer PDL.

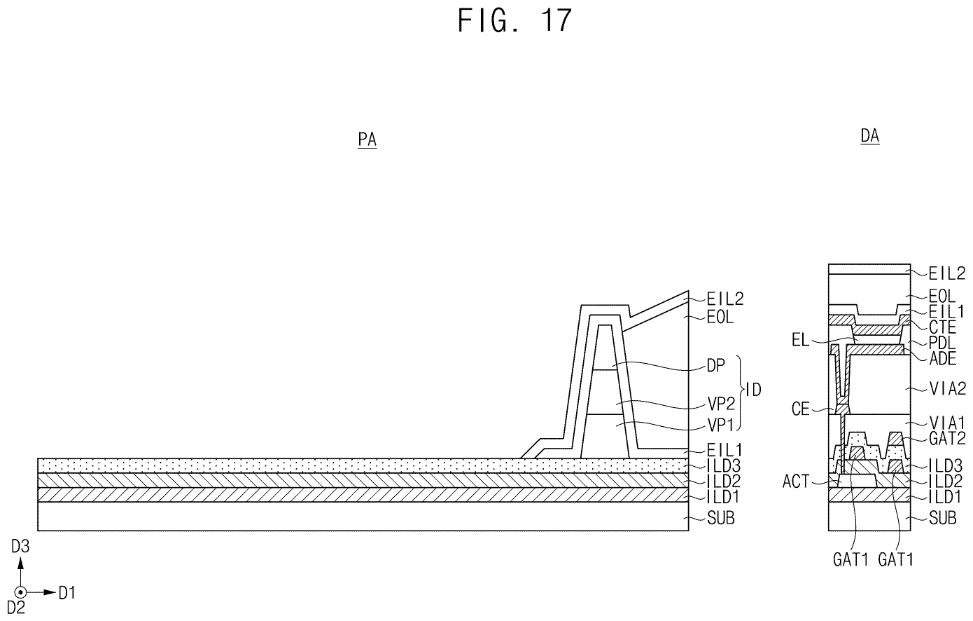

Referring to FIG. 17, in the display area DA, the emission layer EL, the common electrode CTE, the first inorganic encapsulation layer EIL1, the organic encapsulation layer EOL, and the second inorganic encapsulation layer EIL2 may be formed sequentially.

In the peripheral area PA, the first inorganic encapsulation layer EIL1, the organic encapsulation layer EOL, and the second inorganic encapsulation layer EIL2 may be sequentially formed.

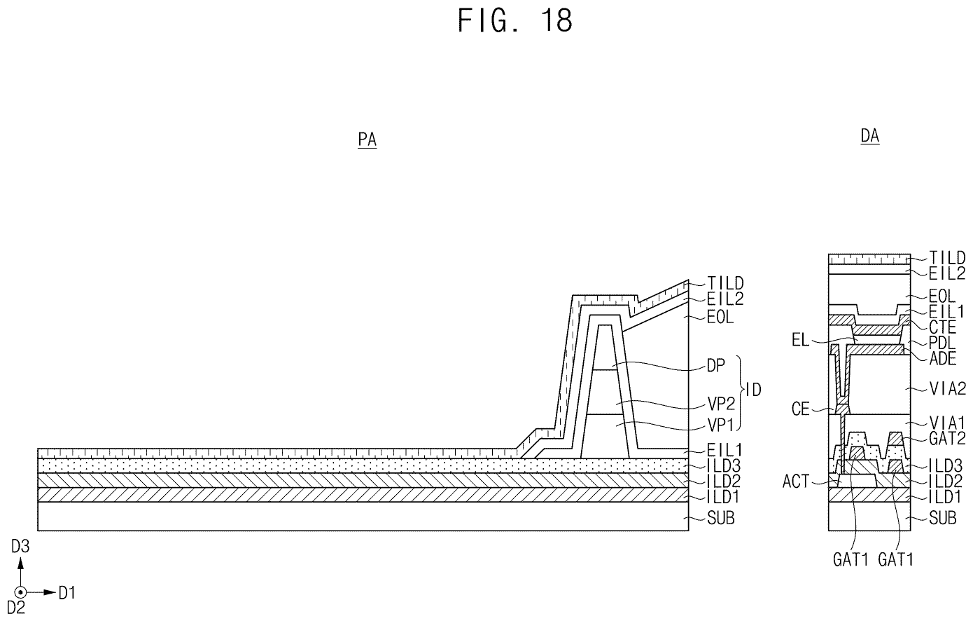

Referring to FIG. 18, the touch insulating layer TILD may be formed together in the display area DA and the peripheral area PA.

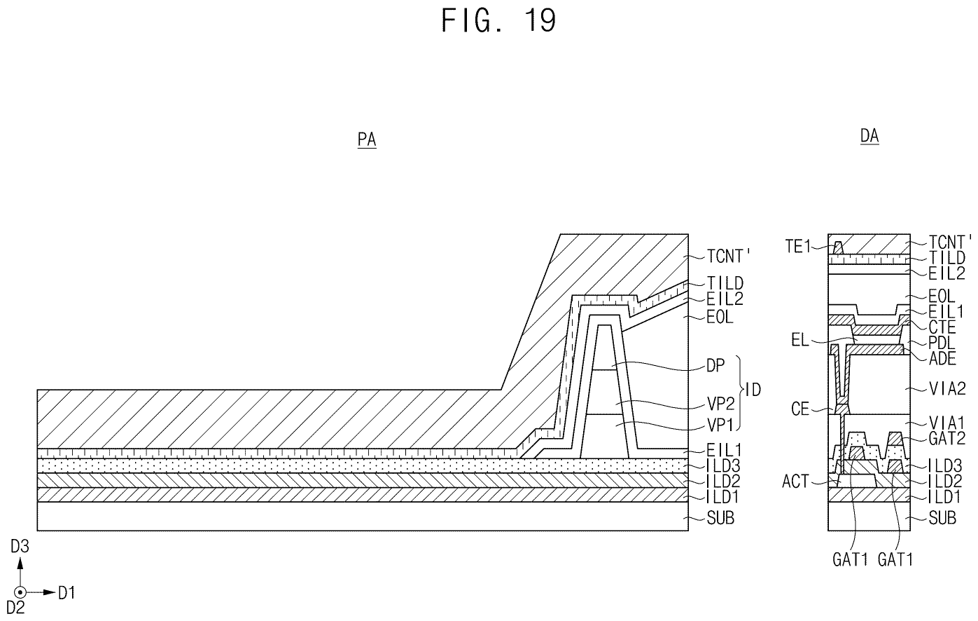

Referring to FIG. 19, in the display area DA, the first touch electrode TE1 may be formed on the touch insulating layer TILD, and a preliminary touch contact layer TCNT′ covering the first touch electrode TE1 may be formed in the display area DA and the peripheral area PA.

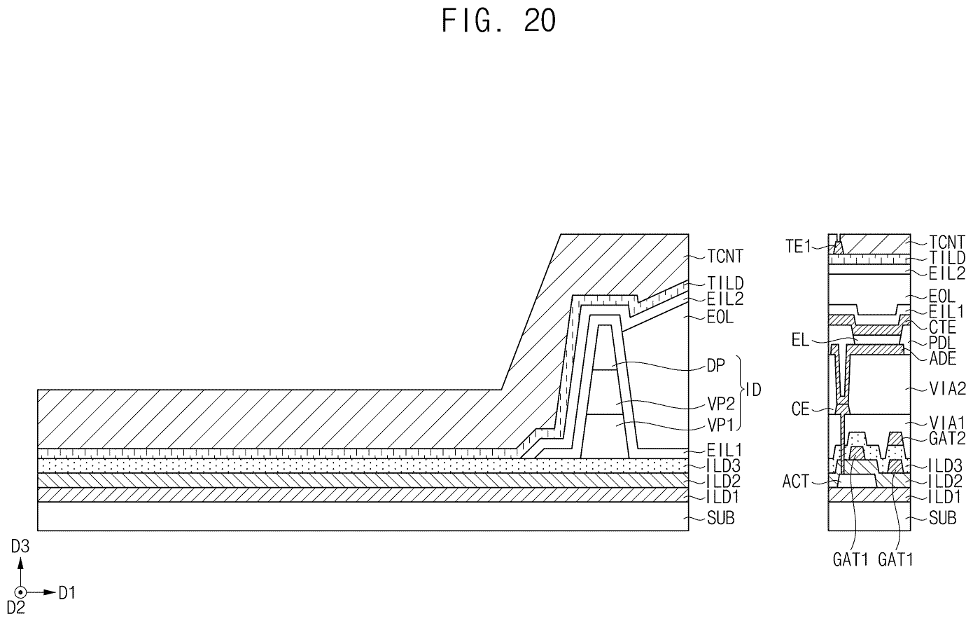

Referring to FIG. 20, in the display area DA, a contact hole may be formed in the preliminary touch contact layer TCNT′, and accordingly, the touch contact layer TCNT may be formed.

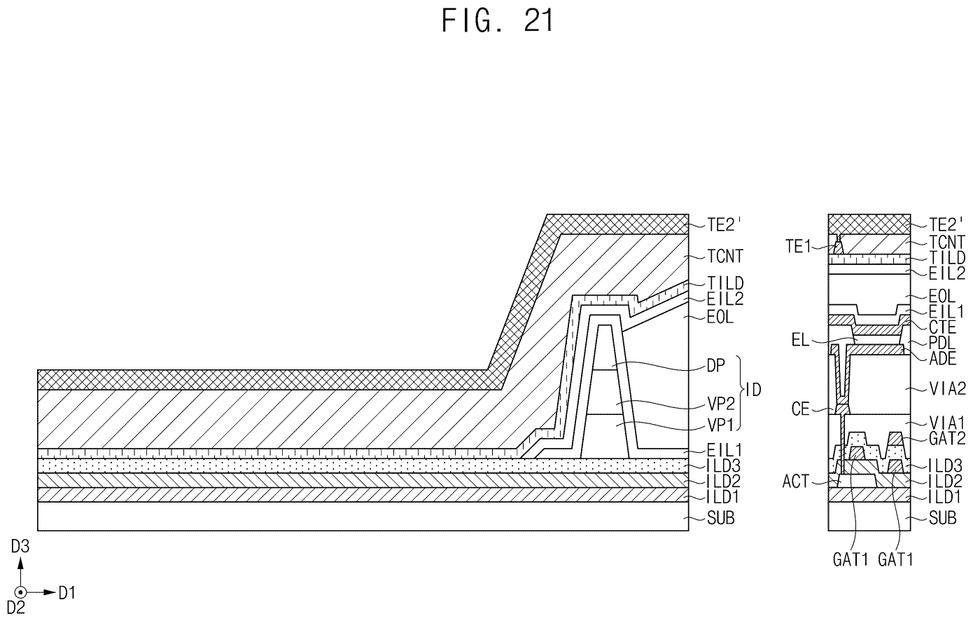

Referring to FIG. 21, a preliminary second touch electrode TE2′ may be formed on the touch contact layer TCNT. For example, the preliminary second touch electrode TE2′ may be formed entirely in the display area DA and the peripheral area PA.

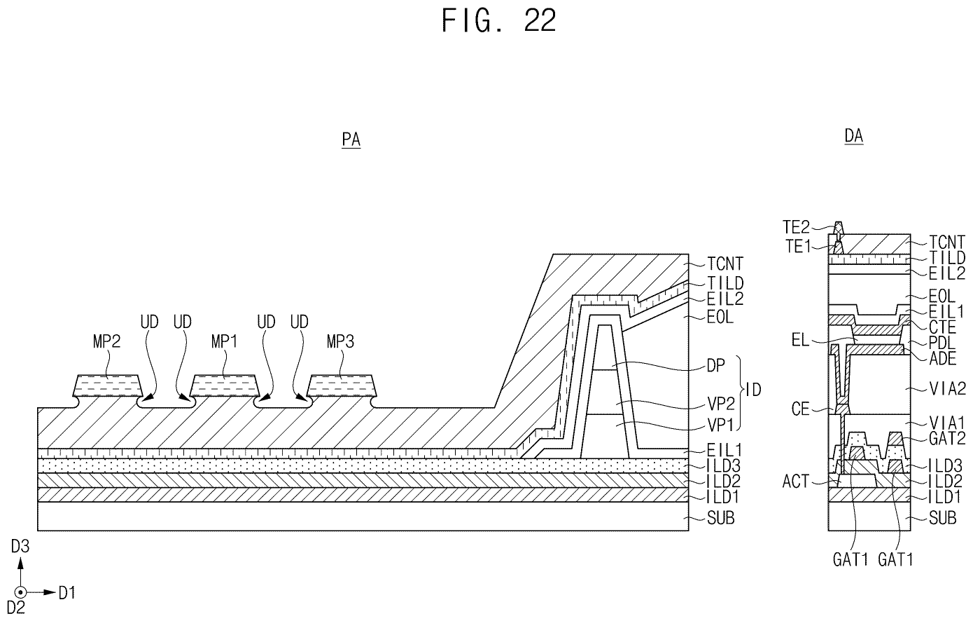

Referring to FIG. 22, the preliminary second touch electrode TE2′ may be patterned. Accordingly, the second touch electrode TE2 may be formed overlapping the display area DA, and the first to third metal patterns MP1, MP2, and MP3 may be formed overlapping the peripheral area PA. For example, the second touch electrode TE2, the first metal pattern MP1, the second metal pattern MP2, and the third metal pattern MP3 may be formed together.

In an embodiment, the undercut shape UD may be formed in the touch contact layer TCNT that contacts the first metal pattern MP1. For example, when performing an isotropic etching process on the preliminary second touch electrode TE2′, the undercut shape UD may be formed in the touch contact layer TCNT contacting the first metal pattern MP1. In addition, the undercut shape UD may be formed in the touch contact layer TCNT contacting the second metal pattern MP2 and the third metal pattern MP3.

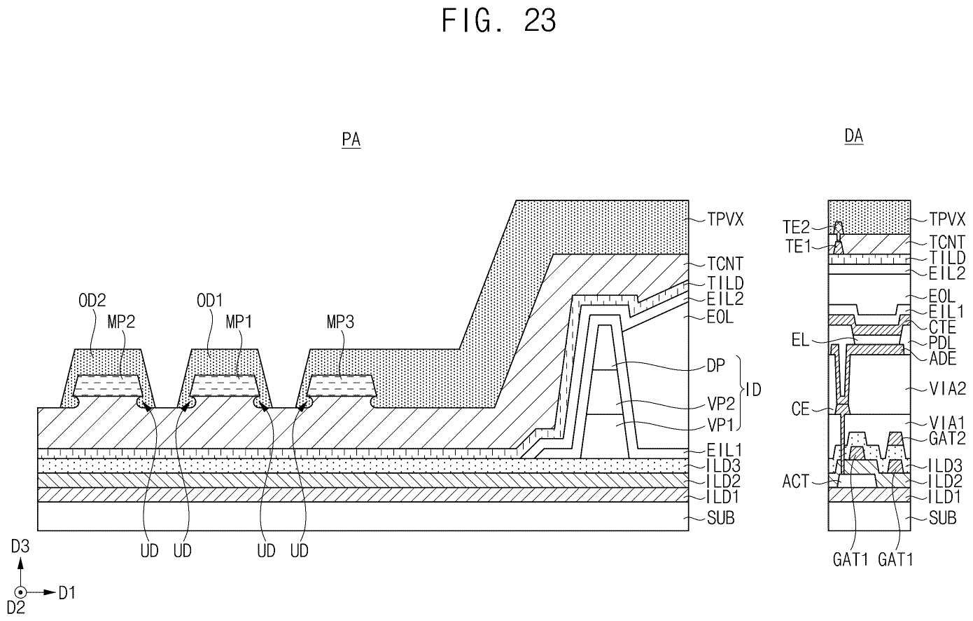

Referring to FIG. 23, the touch protection layer TPVX may be formed in the display area DA.

In the peripheral area PA, the first outer dam OD1 and the second outer dam OD2 may be formed together with the touch protection layer TPVX.

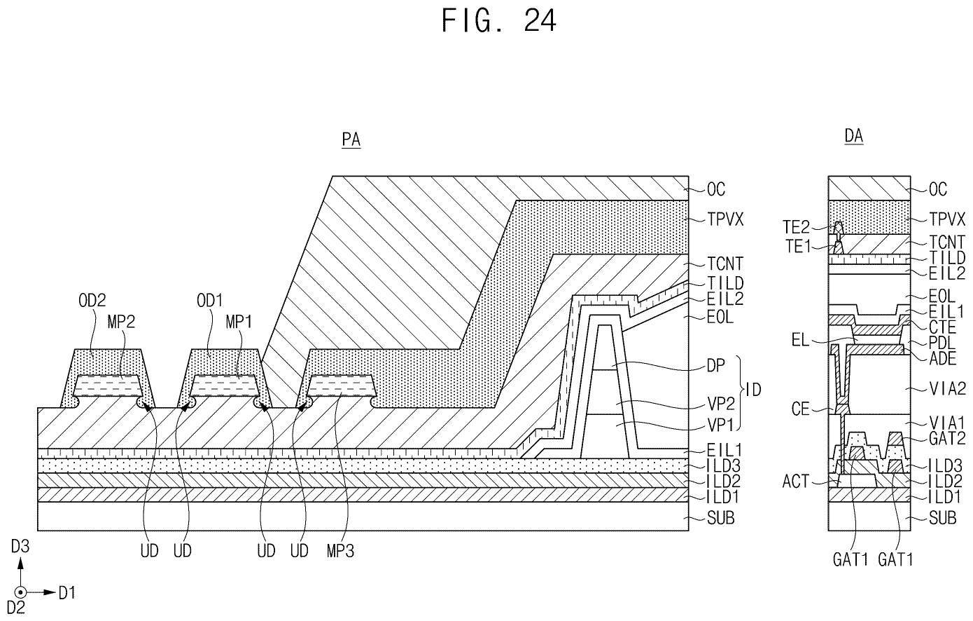

Referring to FIG. 24, the overcoating layer OC may be formed in the display area DA and the peripheral area PA. The overcoating layer OC may extend toward the peripheral area PA bordering the first outer dam OD1.

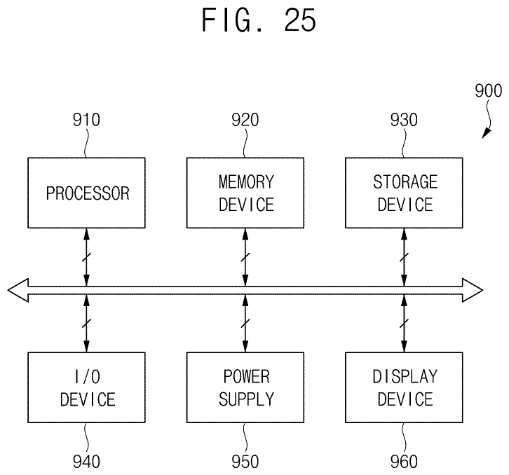

FIG. 25 is a block diagram illustrating an electronic device according to an embodiment of the present invention.

Referring to FIG. 25, in an embodiment, an electronic device 900 may include a processor 910, a memory device 920, a storage device 930, an input/output (“I/O”) device 940, a power supply 950, and a display device 960. Here, the display device 960 may correspond to the display device 1000 of FIG. 1 or the display device 2000 of FIG. 13. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

Although certain embodiments and implementations have been described herein, other embodiments and modifications will be apparent from this description. Accordingly, the inventive concepts are not necessarily limited to such embodiments, but rather to the broader scope of the appended claims and various obvious modifications and equivalent arrangements as would be apparent to a person of ordinary skill in the art.

What is claimed is:

1. A display device, comprising:
a substrate including a display area and a peripheral area adjacent to the display area;
at least one inorganic insulating layer disposed on the substrate and overlapping the display area and the peripheral area;
an emission layer disposed on the inorganic insulating layer and overlapping the display area;
a touch insulating layer disposed on the emission layer;
a touch contact layer disposed on the touch insulating layer;
a touch protection layer disposed on the touch contact layer and overlapping the display area;
at least one outer dam disposed on the inorganic insulating layer, overlapping the peripheral area, including a same material as the touch protection layer, and contacting the inorganic insulating layer; and
an overcoating layer disposed on the touch protection layer.

2. The display device of claim 1, wherein the outer dam directly contacts the inorganic insulating layer.

3. The display device of claim 1, wherein neither the touch insulating layer nor the touch contact layer are disposed between the outer dam and the inorganic insulating layer.

4. The display device of claim 1, wherein the inorganic insulating layer includes an inorganic material, and
wherein each of the touch protection layer and the outer dam include an organic material.

5. The display device of claim 4, wherein the touch contact layer includes an organic material.

6. The display device of claim 1, further comprising:
an active pattern disposed on the substrate;
a first gate electrode disposed on the active pattern; and
a second gate electrode disposed on the first gate electrode.

7. The display device of claim 6, wherein the inorganic insulating layer includes:
a first inorganic insulating layer disposed between the substrate and the active pattern;
a second insulating layer disposed between the active pattern and the first gate electrode; and
a third insulating layer disposed between the first gate electrode and the second gate electrode.

8. The display device of claim 1, further comprising:
an encapsulation layer disposed between the inorganic insulating layer and the touch insulating layer,
wherein the encapsulation layer includes:
a first inorganic encapsulation layer disposed on the inorganic insulating layer;
an organic encapsulation layer disposed on the first inorganic encapsulation layer; and
a second inorganic encapsulation layer disposed on the organic encapsulation layer.

9. The display device of claim 1, further comprising:
a via insulating layer disposed between the inorganic insulating layer and the emission layer, and overlapping the display area; and
at least one inner dam disposed on the inorganic insulating layer, overlapping the peripheral area, including a same material as the via insulating layer, and contacting the inorganic insulating layer.

10. The display device of claim 1, further comprising:
a first touch electrode disposed on the touch insulating layer; and
a second touch electrode disposed on the touch contact layer.

11. A display device, comprising:
a substrate including a display area and a peripheral area adjacent to the display area;
an emission layer disposed on the substrate and overlapping the display area;
a touch insulating layer disposed on the emission layer;
a first touch electrode disposed on the touch insulating layer and overlapping the display area;
a touch contact layer disposed on the touch insulating layer, covering a first touch electrode, and overlapping the display area and the peripheral area;
a second touch electrode disposed on the touch contact layer and overlapping the display area;
a touch protection layer disposed on the touch contact layer, covering the second touch electrode, and overlapping the display area;
at least one metal pattern disposed on the touch contact layer, overlapping the peripheral area, and including a same material as the second touch electrode;
at least one outer dam disposed on the touch contact layer, overlapping the peripheral area, including a same material as the touch protection layer, and covering the metal pattern; and
an overcoating layer disposed on the touch protection layer.

12. The display device of claim 11, wherein the outer dam directly contacts the metal pattern.

13. The display device of claim 11, wherein the touch protection layer and the outer dam include an organic material.

14. The display device of claim 13, wherein the touch contact layer includes an organic material.

15. The display device of claim 11, wherein the metal pattern contacts the touch contact layer in the peripheral area.

16. The display device of claim 15, wherein the touch contact layer contacting the metal pattern has an undercut shape.

17. The display device of claim 11, further comprising:
an active pattern disposed on the substrate;
a first gate electrode disposed on the active pattern;
a second gate electrode disposed on the first gate electrode;
a connection electrode disposed on the second electrode;
a pixel electrode disposed between the connection electrode and the emission layer; and
a common electrode disposed on the emission layer.

18. The display device of claim 17, further comprising:
a first inorganic encapsulation layer disposed on the common layer;
an organic encapsulation layer disposed on the first inorganic encapsulation layer; and
a second inorganic encapsulation layer disposed on the organic encapsulation layer.

19. The display device of claim 11, further comprising:
at least one via insulating layer disposed under the emission layer and overlapping the display area; and
at least one inner dam disposed on the substrate, overlapping the peripheral area, and including a same material as the via insulating layer.

20. An electronic device, comprising:
a display device; and
a power supply configured to provide power to the display device,
wherein the display device comprises:
a substrate including a display area and a peripheral area adjacent to the display area;
at least one inorganic insulating layer disposed on the substrate and overlapping the display area and the peripheral area;
an emission layer disposed on the inorganic insulating layer and overlapping the display area;
a touch insulating layer disposed on the emission layer;
a touch contact layer disposed on the touch insulating layer;
a touch protection layer disposed on the touch contact layer and overlapping the display area;
at least one outer dam disposed on the inorganic insulating layer, overlapping the peripheral area, including a same material as the touch protection layer, and contacting the inorganic insulating layer; and
an overcoating layer disposed on the touch protection layer.
